(19) United States
(12) Patent Application Publication
(10) Pub. No.: US 2021/0082696 A1
(43) Pub. Date: Mar. 18, 2021

(54) SYSTEMS AND METHODS OF FORMATION OF A METAL HARDMASK IN DEVICE FABRICATION

(71) Applicant: Applied Materials, Inc., Santa Clara, CA (US)

(72) Inventors: Xiaoquan MIN, Mountain View, CA (US); Prashant Kumar KULSHRESHTHA, San Jose, CA (US); Kwangduk Douglas LEE, Redwood City, CA (US); Vinay K. PRABHAKAR, Cupertino, CA (US)

(21) Appl. No.: 16/971,239

(22) PCT Filed: Mar. 1, 2019
(86) PCT No.: PCT/US2019/020350

§ 371 Date: Aug. 19, 2020

Related U.S. Application Data
(60) Provisional application No. 62/637,188, filed on Mar. 1, 2018.

(51) Int. Cl. H01L 21/033; H01J 37/32; H01L 21/02

(52) U.S. Cl. CPC H01L 21/0332; H01L 21/02315; H01J 37/321

(57) ABSTRACT

A method of and system for substrate fabrication is disclosed herein. The method includes performing a first plasma-enhanced surface treatment in a chamber prior to disposal of a substrate, then, subsequently, depositing a season material in the process chamber. After depositing the plurality of season materials in the process chamber, a substrate is disposed in the chamber. The substrate is positioned in the process chamber in contact with the season material. A substrate treatment is performed. The substrate treatment can include one or more of: performing a second plasma-enhanced surface treatment, forming a barrier layer on the substrate, or performing a low frequency RF treatment prior to forming a metal-based hardmask film on the substrate. The metal-based hardmask film includes one or more metals.

### BACKGROUND

### Field

Embodiments of the present disclosure generally relate to the manufacture of integrated circuits (IC) employed in semiconductor technologies for both memory and logic application. The fabrication of these ICs may include photolithography as well as a transfer process to transfer the fabricated patterns to substrates. This transfer process may employ masking films.

### Description of the Related Art

Semiconductor devices include film stacks having high aspect ratio features formed therein. The high aspect ratio features can be formed in various operations. Some high aspect ratio features can be formed using hardmask films to form features in film stacks during processing of advanced logic and memory components. Hardmask films may include various metallic materials, non-metallic materials, or combinations of materials depending upon the type of device being fabricated. Hardmask films are designed to withstand long etching processes without degrading. Hardmask films additionally exhibit higher mechanical strength and lower stress as compared to other masking materials. However, conventional hardmasks suffer from delamination issues during processing. Delamination of the hardmask can negatively impact device fabrication including etching as well as downstream operations.

Therefore, there is a need for improved hardmasks and hardmask formation methods.

### SUMMARY

The present disclosure generally relates to systems and methods for the fabrication of devices using metal-based hardmasks, including the configuration and preparation of the systems employed to fabricate these devices. In one example, a method of forming a hardmask includes performing a first plasma-enhanced surface treatment in a process chamber, and, subsequent to performing the first plasma-enhanced surface treatment, a season material is deposited on a plurality of exposed surfaces of the process chamber. Further in this example, subsequent to depositing the season material on the plurality of exposed surfaces of the process chamber, a substrate is positioned in the process chamber, wherein the substrate is in contact with the season material. At least one treatment is performed on the substrate, the at least one treatment including performing a second plasma-enhanced surface treatment, forming a barrier layer on the substrate, or performing a low frequency RF treatment. Subsequent to performing the at least one treatment, a metal hardmask film is formed on the substrate.

In another example, a method of substrate fabrication includes: cleaning a process chamber, and, subsequently, performing a first plasma-enhanced surface treatment in a process chamber. Subsequent to performing the first plasma-enhanced surface treatment, depositing a season material on a plurality of exposed surfaces of the process chamber, the season material comprising at least two of silicon oxide, silicon nitride, amorphous silicon or combinations thereof or combinations thereof; positioning a substrate in the process chamber in contact with the season material; and forming a metal hardmask film on the substrate.

In an example, a device includes: a silicon substrate; a plurality of alternating SiN—SiO₂ layers disposed to form a stack on the silicon substrate; a barrier layer formed on the stack; and a hardmask layer formed on the barrier layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a flow chart of a substrate fabrication method according to embodiments of the present disclosure.

FIG. 2 is a partial cross-sectional view of a process chamber where a barrier layer and a metal-based hardmask film have been formed according to embodiments of the present disclosure.

FIG. 3A-3B are partial schematic views of a showerhead according to embodiments of the present disclosure.

FIGS. 4A-4B are a comparison of two defect scan images of the frontside of substrates fabricated as discussed herein with a tungsten hardmask film.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

In order to achieve higher capacity and lower cost per unit for devices, integrated circuit (IC) manufacturers are advancing semiconductor technologies to reduce critical dimension (CD) sizes during processing, for both logic and memory device applications. A non-collapsing highly etch selective hardmask as discussed herein is used to transfer the pattern from photolithography to the underlying substrates to produce devices with increasingly smaller critical dimensions.

Embodiments of the systems and methods of the present disclosure relate to the formation (deposition) of a defect-free metal-based hardmask on a wide variety of substrate types and geometries. In an embodiment, “defect-free” can mean that less than a predetermined number (“X”) of defect adders (e.g., particle contaminants) of a predetermined diameter are permitted to be present in or on a semiconductor film of a predetermined thickness. In one example, less than 10 defect adders can be present that are greater than 32 nm for a ˜200 \acute{Å}-thick semiconductor films on a 200 mm or 300 mm diameter substrate. In another example, less than 30 defect adders can be present that are greater than 90 nm for a 5 k\acute{Å} thick film.

The substrates discussed herein upon which the metal-based hardmask films are formed can include device substrates that are positioned in a process chamber for operations including film formation and patterning. The substrates discussed herein upon which the metal-based hardmask films (or hardmask material) are formed can further include process chamber surfaces and components, including showerheads, blocker plates, and other components included in the process chamber.

Currently employed films used for hardmasking can have various challenges, including substrate adhesion, absent or inefficient barrier layer(s), and undesirable in-film defects including backside defects. Conventional metal-including hardmask films used in logic applications and memory applications (which may be thicker films than those used in logic applications) exhibit poor, e.g., unusable or undesirable, adhesion on substrates including substrates of silicon oxide, silicon nitride, poly-silicon, amorphous silicon, etc. The poor adhesion can be a result of the diffusion of fluorine (F) radicals (which are generated from WF₆, a commonly used tungsten precursor) through hardmask films towards the hardmask-substrate interface. Once the hardmask-substrate interface is saturated with F radicals, the saturated interface causes hardmask film delamination from the underlying substrate, and, hence, poor adhesion.

Unlike conventional applications, hardmask films discussed herein are used in conjunction with a barrier layer. The barrier layer can also be referred to as an initiation layer herein, and is formed on the substrate prior to hardmask deposition to prevent the diffusion of fluorine. The barrier layer further facilitates sufficient adhesion of metal-hardmask films, including tungsten-hardmask films, on desired substrates. In one example, the hardmask films discussed herein can be formed as a single layer. In another example, the hardmask films discussed herein can be formed as two or more layers. In one example, the hardmask films can be formed on a device substrate and/or on process chamber components in a series of sub-operations.

In addition, the barrier layer discussed herein acts as a seed layer to provide sufficient nucleation sites for a subsequent bulk amorphous metal-based hardmask (“metal hardmask”) film deposition. The barrier layer promotes both the uniform composition and the morphology of metal-based hardmask films, such as tungsten-hardmask films, along (through) the depth of the hardmask film. The barrier layers discussed herein demonstrate similar etch behaviors as bulk tungsten-hardmask film. The similar etch behaviors prevent issues such as profile widening during etching and hardmask residual material left after etching. The similar etch behaviors can also alleviate other challenges presented by barrier layers of materials that behave less similarly to the bulk metal hardmask films employed in various embodiments of the present disclosure.

The metal-based hardmask discussed herein can be deposited using plasma-enhanced deposition methods and modified gas flow distribution schemes. Using the systems and methods discussed herein, metal-based hardmask films having a wide range of dopant concentration (e.g., 10%-80%) are formed. The hardmask films discussed herein can include one or more metals such as tungsten (W), cobalt (Co), titanium (Ti), molybdenum (Mo), yttrium (Y), zirconium (Zr), or other metals or combinations and alloys of metals.

The metal-based hardmask films can be formed to include dopants such as boron, carbon, nitrogen, and silicon, and are deposited on substrates (e.g. oxide, nitride, amorphous silicon, oxide-nitride stack, titanium nitride, silicon, poly-silicon, etc.).

The metal-based hardmask films fabricated according to embodiments of the present disclosure exhibit viable adhesion and are free or substantially free from defects on both the frontside and backside of the substrate. In various examples, a dopant content can be from 10-80 wt. % of a total weight of a metal-hardmask film. In some embodiments, substrates upon which the metal-hardmask films are formed include Si-based stacks, for example, alternating layers of silicon oxide, (SiOₓ) and silicon nitride (SiNₓ) that can range from 32 layers to 256 layers. The stacks are fabricated to be patterned by methods including etching. Masks, including metal-based hardmask discussed herein, can be employed to form these patterns. Accordingly, the metal-based hardmasks discussed herein are formed to withstand etching thicker stacks (for example, 96 or more silicon oxide/silicon nitride layers) than conventional masks. The metal-based hardmasks discussed herein have a reduced likelihood and severity of delamination from the stack's surface. Delamination of a hardmask can lead to substrate defects, undercuts during etching, and/or poor or inconsistent etch selectivity among and between layers of the stack.

Turning back to the barrier layer, in order to be suitable for next generation node applications, the barrier layer is selected as to exhibit similar thermal and mechanical properties and stoichiometry as the bulk hardmask materials (e.g., a tungsten hardmask). The similarity in properties and stoichiometry can prevent profile widening during subsequent etch processes and can prevent unexpected hardmask residual which improves the device yield. Similarly, films formed according to embodiments of the present disclosure can be employed in future generation applications due to viable in-film defect (inclusion) performance. The in-film defect performance of the hardmask films discussed herein facilitates prevention of misaligned profiles during the hardmask open etch operation, thus mitigating subsequent etch profile misalignment and increasing device yield.

During substrate processing, materials used to form metal hardmask films such as tungsten-hardmask films can build up on top-electrode surfaces (“showerhead surfaces”) within a processing chamber. During plasma processing operations within the processing chamber, poor adhesion of deposited metal hardmask films results in flaking or peeling of the metal hardmask films from the top electrode. Conventional metal hardmask films can flake or peel on to substrates or can manifest as in-film particle defects within layers on a processing substrate that can impede etching or other subsequent processes executed on the substrate. Using the systems and methods discussed herein, various methods can be employed alone or in combination to form a metal-based hardmask film. Silicon substrates with stacks greater than 96 layers can be successfully etched while flaking of delamination of metal-based hardmask materials is mitigated.

These systems and methods discussed herein can include operations such as: (1) cleaning the chamber prior to positioning the substrate in the chamber using a blocker plate designed to more evenly distribute gas; (2) performing a plasma-enhanced chamber surface treatment prior to positioning the substrate in the chamber using, for example, ionized/radicalized nitrogen oxide (e.g., N₂O), and ionized/radicalized oxygen and/or helium; (3) performing a plasma-enhanced season material deposition, such as a silicon-rich material, in the chamber prior to positioning the substrate in the chamber (4) subsequent to positioning the substrate in the chamber, performing a hydrogen and/or nitrogen plasma-enhanced surface treatment; (5) independently of or subsequent to (4), while the substrate is in the chamber, forming a barrier layer, for example, a tungsten nitride barrier layer, by performing cycles of soaking the substrate in a precursor and then executing a plasma-enhanced surface treatment which may or may not include a process gas ramping as opposed to holding a gas flow in the chamber at a constant rate during the plasma treatment subsequent to the precursor soak; and/or (6) applying a low frequency RF while the substrate is in the chamber and employing process gas ramping. While the above describes one example, other examples are contemplated. For example, operation (3) can be performed prior to operation (2). In an embodiment, the gas or gases employed at (1) can include argon, NF₃, or oxygen.

Using the systems and methods discussed herein, at least one layer of season (showerhead surface conditioning) material can be used in conjunction with the barrier layer. The barrier layer, which also serves as the seed layer on the showerhead can provide anchoring sites for deposited metal hardmask materials. Additionally, the fluorine diffusion towards a showerhead surface, which would otherwise cause tungsten hardmask and/or season material to peel off (delaminate) is prevented/inhibited by the barrier layer. In some embodiments, during the seasoning of the chamber and thus the showerhead prior to positioning the substrate therein, at least silicon oxide and silicon nitride are employed in various predetermined ratios in order to facilitate protection of chamber components. To form the silicon oxide and/or silicon nitride, silicon, oxygen, and nitrogen precursors are utilized. The precursors are ionized and/or radicalized using RF power to enhance the adhesion of silicon oxide and silicon nitride to the showerhead to account for AlFx formation discussed below. The ratio of the percentages of silicon oxide:silicon nitride employed can include 100:0; 90:10; 80:20; 70:30; 60:40; 50:50, or other ranges of ratios, up to and including 10:90.

A further challenge to metal hardmask manufacture and use is the generation of backside defects that can be caused by aluminum contamination. For example, during plasma/NF₃ clean processes, aluminum-containing substrate supports or heater surfaces are partially converted to AlFₓ. In some examples, the AlFₓ will be transferred to a substrate backside and hence cause undesirable aluminum contamination on the backside of the substrate. In addition, the formed AlFₓ sublimates and deposits on a cold chamber inner surface, such as the showerhead surface.

In contrast to conventional approaches, a layer of season material is deposited on the heater surface right after the plasma/NF₃ dean process. The aluminum diffusion from heater surface to substrate backside is blocked by the season layer to eliminate or mitigate aluminum backside contamination on a substrate. The season layer can also suppress the sublimation of AlFₓ onto the showerhead surface which would otherwise contribute to poor adhesion of the subsequent layers on the showerhead. In addition, the use of silicon oxide and silicon nitride reduce scratching on the backsides of substrates due to the relative softness of the silicon oxide and silicon nitride layers.

Thus, using the systems and methods herein, the adhesion of the hardmask films, which can be tungsten-hardmask films, is improved via (1) a surface treatment, (2) a season materials deposition, (3) and a barrier/seed layer deposition. In one example, the surface treatment applied to the showerhead removes AlFₓ residue to enhance the adhesion of season material. The surface treatment further improves the nucleation of metal hardmask films on barrier/seed layers. The season material exhibits low hardness, adheres well to showerhead surfaces (to enable further processing), and provides anchoring sites for metal hardmask film deposition on showerheads and other surfaces having a barrier layer disposed thereon. The “low” desired hardness of the season material(s) discussed herein can be defined herein as a hardness that is less than 50% of the hardness of the substrate as to not scratch the substrate. In another example, the hardness of the season material(s) is less than 33% the hardness of the substrate, or less than 25% of the hardness of the substrate. Turning to the barrier layer, the barrier layer, in one example, includes properties and stoichiometry as the bulk metal hardmask material, including similar behaviors during the etch process.

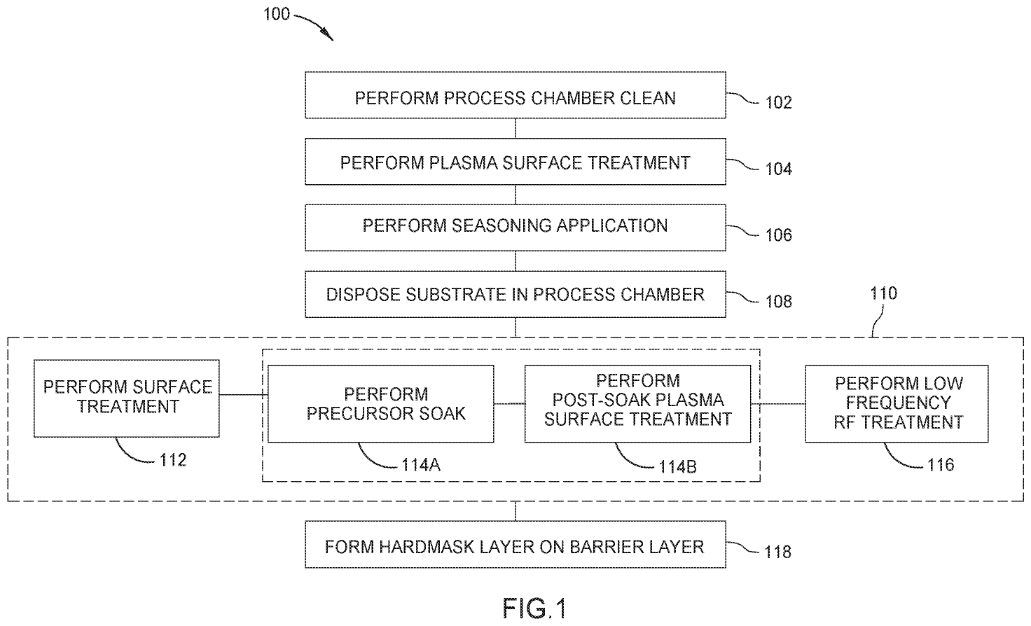

FIG. 1 is a flow chart of a substrate fabrication method 100 according to embodiments of the present disclosure. In some examples, at operation 102, a process chamber is cleaned, for example, using one or more gases including chlorine. In one example, operation 102 is performed prior to deposition of a substrate or substrate batches into the process chamber. Subsequent to the chamber cleaning at operation 102, at operation 104, a first plasma surface treatment is executed in the process chamber. This treatment at operation 104 can include nitrogen oxide (e.g., N₂O) and/or a mixture of oxygen and helium gas. A high frequency RF current (e.g., ˜13.56 MHz) can be applied to ionize or radicalize the nitrogen oxide and/or the mixture of oxygen and helium gas to form a high frequency plasma. In other embodiments, at operation 104, one or more gases such as nitrogen oxide, nitrogen (e.g., N₂), oxygen (e.g., O₂), helium, ammonia (NH₃), diborane (B₂H₆), or propene (C₃H₆) can be employed alone or in various combinations with one or more gases discussed above to generate the high frequency RF plasma.

During the first plasma treatment at operation 104, AlFₓ residue on a surface of a showerhead within the process chamber is converted into aluminum oxide (AlOₓ). At operation 106, subsequent to the first plasma treatment at operation 104 and without a substrate or substrates in the process chamber, one or more layers of season material are deposited on exposed surfaces inside of the process chamber. The one or more layers of season material deposited at operation 106 can include silicon oxide, silicon nitride, amorphous silicon (a-Si), one or more alternating layers of silicon oxide and silicon nitride, one or more alternating layers of silicon oxide and amorphous silicon, one or more alternating layers of silicon nitride and amorphous silicon, etc. The exposed surfaces can include the showerhead surface, the substrate support surface, a chamber bottom, and/or a chamber sidewall. The conversion of the AlFₓ residue into aluminum oxide increases adhesion of subsequently-deposited season materials on the process chamber surfaces and the showerhead. The season layer deposited at operation 106 adheres to the showerhead to provide anchoring sites for subsequent hardmask material deposition at operation 112 discussed below. The season layer disposed at operation 106, which can be less than 50 angstroms and in some examples less than 30 angstroms or about 20 angstroms or less, prevents fluorine radical diffusion onto the showerhead when fluorine is subsequently introduced into the process chamber and the showerhead is exposed thereto. As discussed above, fluorine radical diffusion results in reaction of fluorine with the aluminum showerhead, forming, AlFₓ, which results in delamination or flaking of materials from the showerhead which can cause defects on front side surfaces of substrates.

The season materials discussed herein are soft in terms of hardness. In one example, the season materials discussed herein have a hardness that is less than 50% of the hardness of a substrate. In another example, the season materials discussed herein have a hardness that is less than a third of the substrate hardness. The hardness of the season materials, as compared to the hardness of the substrate, contributes to the reduction of the substrate backside scratching, when a substrate is placed in contact therewith. Backside scratching can occur during subsequent lithography processes when higher hardness materials (e.g., those closer to the substrate's hardness than the materials discussed herein as season materials used at operation 106) are employed. The season materials deposited at operation 106 can further act to suppress the diffusion of AlFₓ from the substrate support surface to the substrate backside, which would otherwise result in aluminum contamination of the substrate. At operation 108, a substrate or batch of substrates is positioned in the process chamber and one or more processing operations, such as deposition, etch, annealing, lithography, or the like, can occur prior to the pre-hardmask treatment at substrate treatment operation 110.

At substrate treatment operation 110, one or more substrate treatment sub-operations can be executed to form a barrier layer. The formation of the barrier layer, as discussed herein, facilitates and promotes formation of a metal hardmask film at operation 118 (discussed below). The hardmask films discussed herein are capable of withstanding etching and further processing due to the improved adhesion of the hardmask film to the substrate via the barrier layer. In an embodiment, at a first sub-operation 112 at substrate treatment operation 110 an initial hydrogen-and-nitrogen plasma-enhanced surface treatment is applied to the season layer. The one or more sub-operations that can be performed at substrate treatment operation 110 can be optionally performed alone or in combination, as discussed below. In some examples, the one or more sub-operations at substrate treatment operation 110 are performed in series.

During the hydrogen and nitrogen surface treatment at the first sub-operation 112 at substrate treatment operation 110, hydrogen (H) bombardment creates surface Si—H bonds. The Si—H bonds serve as the nucleation sites on the barrier layer for subsequent or barrier layer deposition (at sub operations 114A and 114B) and/or hardmask layer at operation 118 (discussed below). Metal precursors, such as WF₆, interact with the nucleation sites to facilitate film formation. When 110 is performed in a cyclical process such that hydrogen and nitrogen treatment occurs on a tungsten-containing layer, hydrogen bombardment (after sub-operations 114A and 114B) further creates nitrogen vacancies in the treated films, trapping fluorine radicals during metal hardmask deposition or, subsequently, barrier layer deposition. In an example where the metal hardmask and/or barrier layer includes tungsten, the hydrogen bombardment further increases the hydride content of the tungsten layer when the tungsten layer is converted into a tungsten nitride layer. The tungsten nitride layer serves as the barrier layer for tungsten hardmask films, or other metal-based hardmask films discussed herein, to improve adhesion and nucleation.

In another embodiment, which can be combined with other examples and embodiments herein, at a second sub-operation 114A of substrate treatment operation 110, a precursor, such as WF₆, is introduced and adsorbed on the substrate surface in a (quasi-)monolayer. Subsequently, a plasma-enhanced hydrogen-and-nitrogen surface treatment can be executed at a third sub-operation 114B at substrate treatment operation 110. The third sub-operation 114B exposing the substrate to hydrogen and nitrogen plasma, and reduces the WF₆ to tungsten (W). Further at the third sub-operation 114B, the tungsten layer is converted into tungsten-nitride. In one example, which can be combined with other examples herein, the first sub-operation 112 can be combined with the second sub-operation 114A and the third sub-operation 114B.

In substrate treatment operation 110, the use of an initial hydrogen and nitrogen surface treatment of the first sub-operation 112 eliminates the use of conventional boron (B) or silicon (Si) precursors for the formation of a tungsten layer on substrates. The use of boron or silicon-containing precursors in conventional processes can cause issues for process flow/device fabrication due to boron or silicon contamination of materials disposed on the substrate.

The thickness of the tungsten-nitride (WN) layer formed during substrate treatment operation 110 can be controlled via adjusting the number of process cycles. A single cycle of the second sub-operation 114A and the third sub-operation 114B can be repeated during the substrate treatment operation 110 for a plurality of iterations until a barrier layer having a thickness within a predetermined thickness range is formed. In an embodiment, in order to form a metal-based barrier layer using tungsten at the second sub-operation 114A and the third sub-operation 114B, a plurality of nucleation sites is formed on the substrate for tungsten nucleation. In conventional processes, the boron or silicon precursor can adsorb on the substrate surface and then chemically react with tungsten to nucleate tungsten on the substrate. However, this can cause boron or silicon residual from unreacted precursors. The boron or silicon residual formation can hamper the formation of the hardmask film and can inhibit downstream operations. By using an H₂/N₂ treatment in the first sub-operation 112 at substrate treatment operation 110, surface-dangling bonds are formed which serve as tungsten nucleation sites. In this example, the use of boron or silicon precursors is eliminated.

In one example, a cycle of the second sub-operation 114A and the third sub-operation 114B can form a barrier layer of about 2 Å-4 Å thick. The thickness control of the barrier layer via the cyclic operations improves the tunability of the barrier layer properties, in contrast to bulk deposition methods that can be geared towards the deposition of thicker film layers (such as 20 angstroms to 40 angstroms or greater). The cyclical deposition process utilized at the second sub-operation 114A and the third sub-operation 114B can be used alone or in combination with the first sub-operation 112 in substrate treatment operation 110. In another example, the cyclical deposition process utilized at the second sub-operation 114A and the third sub-operation 114B can be used alone or in combination with a fourth sub-operation 116 at substrate treatment operation 110. In this example, the cyclic deposition process is not dependent on plasma distribution. Rather, one or more parameters of the soaking at the second sub-operation 114A at substrate treatment operation 110, for example, duration, precursor type, and precursor concentration, enable angstrom-level control of the barrier layer formation. The tunability and control of barrier layer formation enables consistency in overlaying layer formation, such as the hardmasks discussed herein, across a substrate, independent of plasma distribution in the process chamber.

In another example, the barrier layer formed by one or more cycles of the second sub-operation 114A and the third sub-operation 114B can be formed to a thickness of about 5 Å to about 50 Å. In other examples, the barrier layer formed by one or more cycles of the second sub-operation 114A and the third sub-operation 114B can be formed to a thickness of about 15 Å to about 25 Å thick. In still other examples, the barrier layer formed by one or more cycles of the second sub-operation 114A and the third sub-operation 114B can have a target thickness of 20 Å. In some embodiments, one or more cycles of the second sub-operation 114A and the third sub-operation 114B are executed in a high frequency (RF) environment at about 13.56 MHz or greater.

In some embodiments, gas ramping can be employed at one or more of the second sub-operation 114A and the third sub-operation 114B at substrate treatment operation 110. Gas ramping is defined herein as adjusting a flow or one or more precursor gases into the process chamber such that the gas flow rate varies over a predetermined gas flow range. Depending upon the embodiment, the gas flow can be either ramped up (increasing gas flow) and/or down (decreasing gas flow) during one or more of the second sub-operation 114A and the third sub-operation 114B at substrate treatment operation 110. In contrast to conventionally employed instantaneous gas flow, the gas ramping discussed herein can be configured for a target gas flow rate that can take from 5 seconds to 30 seconds to achieve. During instantaneous gas flow, the initiation of gas flow during processing causes a target flow rate or range to be reached upon initiating the gas flow. This comparatively slower ramping according to embodiments herein can promote and enable increased and thus sufficient time for nucleation of the barrier layer in contrast to conventional methods. In one example, gas ramping can increase the flow of WF₆ from 0 sccm to 85 sccm within 5 seconds using a 17 sscm/s ramp rate. The gas ramping, in some embodiments, is implemented together with the prior plasma-enhanced hydrogen-nitrogen surface treatment at the first sub-operation 112 of substrate treatment operation 110. In this example, the barrier layer formed during substrate treatment operation 110 facilitates sufficient adhesion of hardmasks onto different substrates, which would otherwise have reduced adhesion in the absence of a barrier layer. The barrier layer deposited during ramping operations exhibits the same composition and/or properties as a hardmask film subsequently formed therein. The similarity in behavior between the barrier layer and the bulk hardmask film prevents or reduces the severity of issues such as profile widening following etch processes, or the presence of hardmask residue, or other challenges of hardmask formation as discussed herein.

Optionally, a fourth sub-operation 116 may be utilized. During the fourth sub-operation 116 of substrate treatment operation 110, a low frequency RF treatment can be employed while a plasma formed from nitrogen and/or hydrogen is present in the process chamber. This low frequency RF treatment can be performed below 13.56 MHz, for example, at 2 MHz, 350 KHz, or other frequencies as appropriate for various embodiments. This can correspond to the application of a bias to the substrate support from between 200 W-300 W, in comparison to a high frequency RF treatment that can occur above about 600 W. The low frequency RF treatment at the fourth sub-operation 116 at substrate treatment operation 110 can be employed in conjunction with or independently of the first sub-operation 112. In another example, which can be combined with other examples herein, the fourth sub-operation 116 can be done in addition to the second sub-operation 114A and the third sub-operation 114B at substrate treatment operation 110.

At operation 118, a metal hardmask film is formed on the barrier layer. The metal hardmask film is formed, for example, to a thickness of about 0.2 microns to a thickness of about 2.0 microns. In one example, the metal hardmask film formed at operation 118 has a dopant concentration from about 10% to about 80%. The one or more dopants included in the metal hardmask film can include as boron, carbon, nitrogen, or silicon. The hardmask films can formed at operation 118 include one or more metals such as tungsten (W), cobalt (Co), titanium (Ti), molybdenum (Mo), yttrium (Y), zirconium (Zr), or other metals or combinations and alloys of metals.

As discussed herein, the systems used to fabricate film stacks and metal-based hardmask films can be configured in various operational states to perform operations and sub-operations via a controller. The controller transmits programming information to various elements in the system, for examples, heater elements, pressure elements, gas flow elements, and/or substrate handling elements.

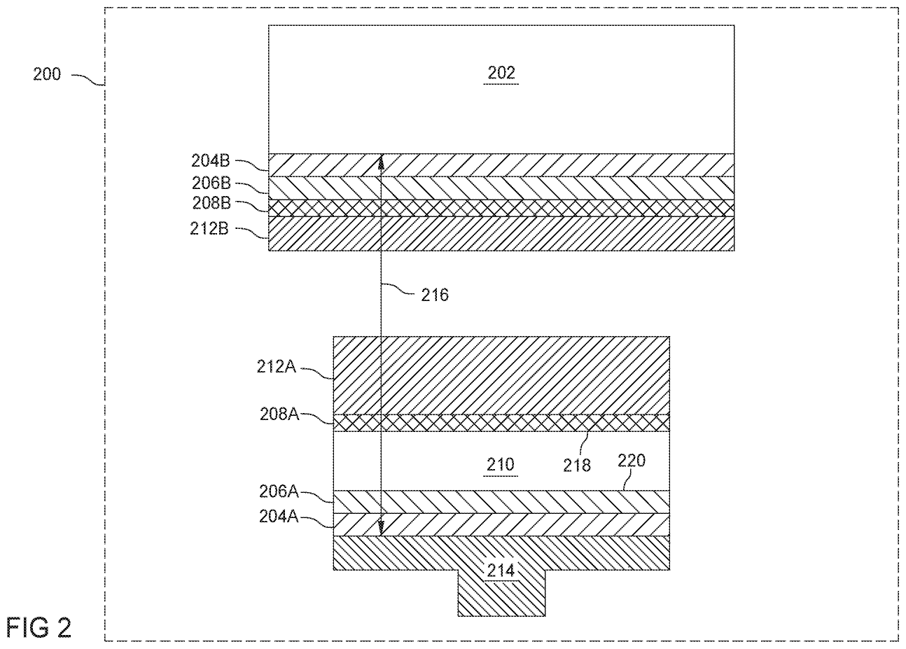

FIG. 2 is a cross-sectional view of a process chamber 200 where a barrier layer and a metal-based hardmask film have been formed according to embodiments of the present disclosure. The process chamber 200 includes a showerhead 202 disposed parallel to and separated from a substrate support assembly 214 by a distance 216. In an embodiment, the substrate support assembly 214 can include a heater, and/or other components, some of which are discussed below. The substrate support assembly 214 is in contact with a first AlFₓ residue layer 204A. The showerhead 202 is in contact with a second AlFₓ residue layer 204B. The season layer discussed herein can be formed as a first season layer 206A on the first AlFₓ residue layer 204A and a second season layer 206B on the second AlFₓ residue layer 204B.

A substrate 210 is positioned on and in direct contact with the first season layer 206A. A first barrier layer 208A is formed on a first side 218 of the substrate 210. A second barrier layer 208B is formed on the second season layer 206B. A first metal hardmask film 212A is formed on the first barrier layer 208A. Metal hardmask material 212B will also form on the second barrier layer 208B. While various layer thicknesses are shown in FIG. 2, this is done for ease of illustration and is not a limiting illustration of the thicknesses or of the relative thicknesses of the components shown.

While FIG. 2 illustrates one embodiment, other embodiments are also contemplated. For example, in other embodiments, the substrate 210 can include an additional barrier layer (not shown) formed on a bottom (backside) surface 220 of the substrate 210 that is opposite the first side 218 of the substrate 210. The additional barrier layer on the backside surface 220 of the substrate 210 can be formed in a similar manner to that is used to form the barrier layer at substrate treatment operation 110 as discussed in the substrate fabrication method 100. The additional barrier layer protects the backside surface 220 from AlFₓ contamination.

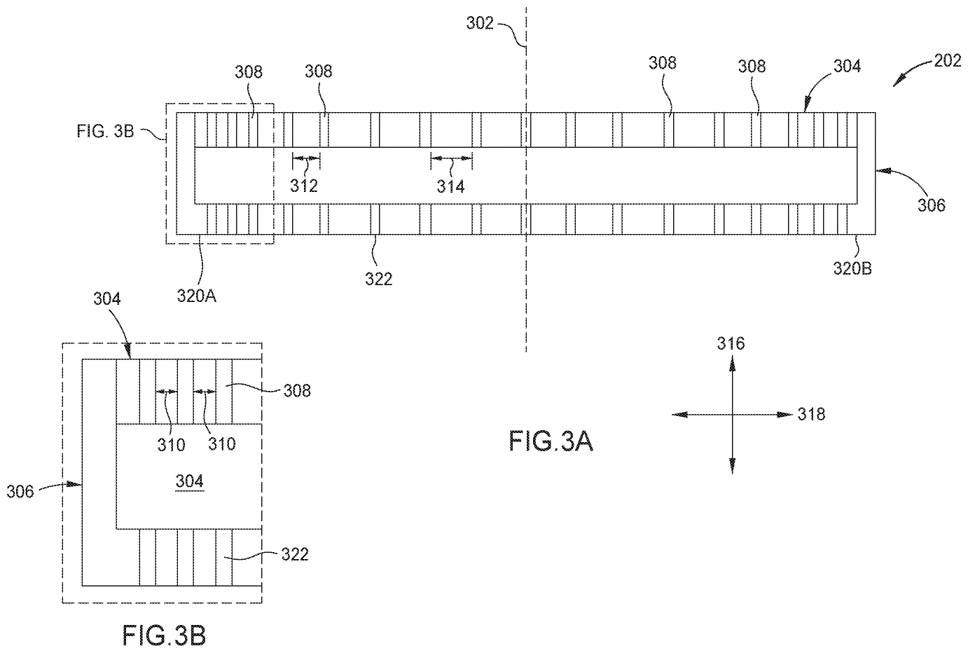

FIG. 3A and FIG. 3B are partial schematic views of a showerhead according to embodiments of the present disclosure. In the example in FIG. 3A, the showerhead 202 includes a blocker plate 304 and a faceplate 306. FIG. 3A further includes a centerline 330 disposed centrally through the blocker plate 304 and the faceplate 306.

A plurality of blocker plate apertures 308 are formed in the blocker plate 304. A plurality of faceplate apertures 322 are formed in the faceplate 306. In one example, the blocker plate 304 is coupled to the faceplate 306 with a gap therebetween defining a plenum. In this example, a position of each of the plurality of faceplate apertures 322 corresponds to a position of (e.g., axially aligned with) each of the plurality of blocker plate apertures 308. Alternatively, some or all of the blocker plate apertures 308 are offset from the faceplate apertures 322. In other example, there can be no or minimal gap formed in between the blocker plate 304 and the faceplate 306. In some examples (not shown here), which can be combined with other examples herein, less than all of the positions of each blocker plate aperture of the plurality of blocker plate apertures 308 corresponds to a position of each of the plurality of faceplate apertures 322. The plurality of blocker plate apertures 308 can be spaced apart at a plurality of differing distances relative to one another. FIG. 3A shows a first spacing 310, a second spacing 312, and a third spacing 314. While the plurality of blocker plate apertures 308 are shown in FIG. 3A as being perpendicular to an axis 318 and parallel to an axis 316, in alternate embodiments, some or all of the plurality of blocker plate apertures 308 can be at an angle relative to the axis 318 other than 90 degrees. In one example, some or all of the plurality of blocker plate apertures 308 can be angled towards or away from the centerline 302.

In an embodiment, the plurality of blocker plate apertures 308 has the first spacing 310 of apertures as measured from a first edge 320A of the blocker plate 304. A second edge 320B is also shown for reference opposite the first edge 320A. The various features shown on a first side of the centerline 302 (e.g., the side closest to the first edge 320A) are mirrored across the centerline 302. In one example, the first spacing 310 between adjacent apertures of the plurality of blocker plate apertures 308 is less than a second spacing 312 between adjacent blocker plate apertures of the plurality of blocker plate apertures 308. In another example, which can be combined with other examples herein, the second spacing 312 between adjacent blocker plate apertures of the plurality of blocker plate apertures 308 can be less than a third spacing 314 between adjacent blocker plate apertures 308. In this example, the relative spacing of the plurality of blocker plate apertures 308 can increase towards the centerline 302 of the blocker plate 304. The plurality of blocker plate apertures 308 can be configured in various manners in different designs of blocker plates in order to evenly distribute gas (indicated by the dashed arrows) in the process chamber 300. This design is in contrast to, for example, a blocker plate having an evenly-spaced distribution of apertures. An evenly-spaced distribution of apertures can cause gas to be received in the process chamber 300 in the center region of a process chamber 300, for example, a position in a process chamber coaxial with the centerline 302. Thus, an evenly-spaced distribution of apertures may not evenly distribute gas in the process chamber 300.

While the plurality of blocker plate apertures 308 in FIG. 3A is shown to be approximately similar diameters, it is contemplated that the diameter of each aperture of the plurality of blocker plate apertures 308 can vary in a blocker plate. In one example, the blocker plate 304 includes an “aperture gradient.” In a blocker plate having an aperture gradient, the plurality of blocker plate apertures 308 closer to the edges 320A and 320B of the blocker plate 304 have larger diameters than the plurality of blocker plate apertures 308 located closer towards the centerline 302 of the blocker plate 304. In some examples, the aperture gradient of a blocker plate can be configured such that in some examples, there is a higher concentration of blocker plate apertures in the plurality of blocker plate apertures 308 per surface area towards the edges 320A and 320B of the blocker plate 304 than towards the centerline 302. The aperture gradient of the blocker plate 304 can be configured the higher concentration of apertures per surface area of blocker plate apertures 308 towards the edges 320A and 320B of the blocker plate 304. This higher concentration is in comparison to the blocker plate apertures 308 of the plurality of blocker plate apertures 308 that are located closer to the centerline 302. The aperture gradient of the blocker plate 304 can be tuned to enable and promote improved gas flow, including improved gas flow distribution towards the edges 320A/320B of the faceplate 306.

Using the systems and methods discussed herein, an overall gas conductance is increased and the gas distribution of gas and plasma in a process chamber is modified to improve uniformity to reduce total cleaning time. The increased gas conductance acts to suppress AlFₓ formation. Thus, the increased gas conductance improves adhesion of season layer on a showerhead and reduces in-film defects. The distribution of process gases, especially at the centerline 302 in contrast to the distribution of process gases at the first edge 320A and the second edge 320B, can be adjusted via the configuration of the blocker plate 304. The control of the uniform distribution of process gases enables control of the hardmask film uniformity as well as the adhesion behavior of the hardmask film.

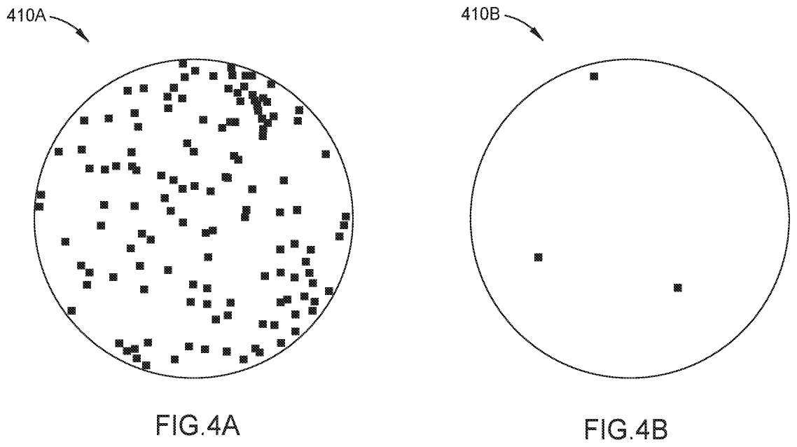

FIGS. 4A-4B are defect scan images of the frontside of substrates fabricated as discussed herein with a tungsten-hardmask film. FIG. 4A shows a first defect scan image of a substrate 410A fabricated without the plasma and season treatments at operations 104 and 106 in FIG. 1. The substrate of FIG. 4A shows more than 200 in-film defects on the backside of a substrate. In contrast, FIG. 4B shows a second defect scan image of a substrate 410B fabricated according to embodiments of the present disclosure. The substrate shown in FIG. 4B was fabricated using the hydrogen and nitrogen plasma and season treatments that can be similar to those discussed at operations 104 and 106 in FIG. 1. The substrate in FIG. 4B shows only 4 defects.

Thus, using the systems and methods herein, metal hardmask film adhesion is improved, resulting in a longer life of the process chamber components and a reduced incidence and severity of substrate defects. Hardmask films fabricated on surfaces without a barrier layer in between the hardmask film and the substrate have poor adhesion, increasing the likelihood of delamination. In contrast, the metal hardmask films formed on a barrier layer according to embodiments of the present disclosure exhibit improved adhesion. Accordingly, the metal hardmask films formed on a barrier layer do not exhibit peeling or delamination, or exhibit a reduced likelihood and/or severity of peeling or delamination. The metal hardmask films discussed herein can be formed not only on process chamber components, but also on substrates used in semiconductor device components.

Surface treatments applied to the showerhead remove AlFₓ residue which enhances the adhesion of season material to the showerhead and improves the adhesion of subsequently deposited layers including hardmask films and/or materials. The season material adheres well to showerhead surfaces, reducing the likelihood of substrate defects due to flaking. The season material further provides anchoring sites for metal hardmask film deposition on showerheads and other surfaces of the process chamber having a barrier layer disposed thereon. When a barrier layer is employed, the one or more materials selected for the barrier layer can have substantially similar material properties such as etch selectivity and/or stoichiometry as the one or more metals included in the metal hardmask. The selection of materials with similar material properties and/or stoichiometry improves adhesion of the metal hardmask film to the barrier layer.

While the foregoing is directed to embodiments of the present disclosure, other and further embodiments of the disclosure may be devised without departing from the basic scope thereof, and the scope thereof is determined by the claims that follow.

What is claimed is:

1. A method of forming a hardmask, comprising:
performing a first plasma-enhanced surface treatment in a process chamber;
subsequent to performing the first plasma-enhanced surface treatment, depositing a season material on a plurality of exposed surfaces of the process chamber;
subsequent to depositing the season material on the plurality of exposed surfaces of the process chamber, positioning a substrate in the process chamber and in contact with the season material;
performing a treatment on the substrate, the treatment comprising at least one of:
performing a second plasma-enhanced surface treatment;
forming a barrier layer on the substrate; and
performing a low frequency RF treatment; and
forming, subsequent to performing the at least one treatment, a metal hardmask film on the substrate.

2. The method of claim 1, wherein the season material comprises at least two of silicon oxide, silicon nitride, amorphous silicon or combinations thereof, wherein the season material comprises a hardness that is less than half of a hardness of the substrate.

3. The method of claim 1, wherein the first plasma-enhanced surface treatment includes introducing a gas into the process chamber through a blocker plate comprising apertures with unequal spacing therebetween.

4. The method of claim 1, wherein forming the barrier layer comprises at least one cycle of soaking the substrate in a precursor for a first period of time to form a target barrier layer thickness and, subsequently, performing a plasma-enhanced treatment for a second period of time.

5. The method of claim 4, wherein the target barrier layer thickness is from about 3 angstroms to about 50 angstroms.

6. The method of claim 4, wherein, during the second period of time, a plurality of gases employed in the plasma-enhanced treatment is ramped up to a target gas flow rate over a predetermined period of gas flow time.

7. The method of claim 6, wherein the predetermined period of gas flow time is from about 5 seconds to about 30 seconds.

8. A method of substrate fabrication, comprising:
cleaning a process chamber;
subsequently, performing a first plasma-enhanced surface treatment in a process chamber;
subsequent to performing the first plasma-enhanced surface treatment, depositing a season material on a plurality of exposed surfaces of the process chamber, the season material comprising at least two of silicon oxide, silicon nitride, amorphous silicon or combinations thereof or combinations thereof;
positioning a substrate in the process chamber in contact with the season material; and
forming a metal hardmask film on the substrate.

9. The method of claim 8, wherein the metal hardmask film comprises at least one of tungsten (W), cobalt (Co), titanium (Ti), molybdenum (Mo), yttrium (Y), zirconium (Zr), or alloys or combinations thereof, and a dopant comprising at least one of boron, carbon, nitrogen, or silicon.

10. The method of claim 8, further comprising: subsequent to positioning the substrate in the process chamber, and prior to forming the metal hardmask film, performing a treatment on the substrate comprising at least one of:
performing a second plasma-enhanced surface treatment;
forming a barrier layer on the substrate; and
performing a low frequency RF treatment.

11. The method of claim 10, wherein the metal hardmask film includes a first metal comprising tungsten (W), cobalt (Co), titanium (Ti), molybdenum (Mo), yttrium (Y), or zirconium (Zr), and the barrier layer includes the first metal.

12. The method of claim 10, further comprising:
during the forming of the barrier layer, introducing a plurality of process gases to the process chamber, and
performing gas ramping during the forming of the barrier layer, wherein, during the gas ramping, a target gas flow of the plurality of process gases is achieved in the process chamber in a time period from 5 second to 30 seconds after introducing the plurality of process gases to the process chamber.

13. A device comprising:
a silicon substrate;
a stack including plurality of alternating silicon nitride and silicon oxide layers formed on the silicon substrate;
a barrier layer formed on the stack; and
a hardmask film formed on the barrier layer.

14. The device of claim 13, wherein the hardmask film comprises a first metal comprising tungsten (W), cobalt (Co), titanium (Ti), molybdenum (Mo), yttrium (Y), zirconium (Zr), or alloys or combinations thereof, and a dopant comprising at least one of boron, carbon, nitrogen, or silicon.

15. The device of claim 14, wherein the barrier layer has a thickness within a range of about 5 angstroms to about 30 angstroms.
